(19) United States
(12) Patent Application Publication
(10) Pub. No.: US 2023/0400781 A1
(43) Pub. Date: Dec. 14, 2023

(54) Method of Analyzing Metrology Data

(71) Applicant: Bruker Nano, Inc., Santa Barbara, CA (US)

(72) Inventors: Vladimir Fonoberov, Santa Barbara, CA (US); Sean Hand, Santa Barbara, CA (US); David Fey, Shorewood, WI (US)

(21) Appl. No.: 18/209,040

(22) Filed: Jun. 13, 2023

Related U.S. Application Data
(60) Provisional application No. 63/352,120, filed on Jun. 14, 2022.

(51) Int. Cl. G03F 7/00

(52) U.S. Cl. CPC G03F 7/70655; G03F 7/706845

(57) ABSTRACT

The preferred embodiments are directed to a metrology method used, for example, in recess analysis in semiconductor fabrication that includes using atomic force microscopy (AFM) data of a sample having an array of 2D-periodic features to generate a sample image, and calculating a periodicity of the features. The method identifies the peaks in the periodicity to determine a feature period and a lattice angle, and constructs a lattice mask that is registered to the image to perform an alignment calculation. The mask is offset, and alignment calculation made, to optimize cost.

### CROSS-REFERENCE TO RELATED APPLICATIONS

This application claims priority under 35 USC § 1.119(e) to U.S. Provisional Patent Application Ser. No. 63/352,120, filed Jun. 14, 2022. The subject matter of this application is hereby incorporated by reference in its entirety.

### BACKGROUND OF THE INVENTION

### Field of the Invention

The preferred embodiments relate to the field of analyzing atomic force microscopy data. In particular, it relates to analyzing spatial and topographical data of sample features, e.g., periodic feature detection in a lattice. The preferred embodiments are particularly useful for making measurements in high throughput applications, for example, performing recess analysis in semiconductor fabrication.

### Description of Related Art

Scanning probe microscopes such as atomic force microscopes (AFMs) are devices which employ a probe having a tip, the tip interacting with the surface of a sample with appropriate forces to characterize the surface down to atomic dimensions. Generally, the probe is introduced to a surface of a sample and by providing relative scanning movement between the tip and the sample, surface characteristic data can be acquired over a particular region of the sample, and a corresponding map of the sample can be generated.

Overall, the instrument is capable of creating relative motion between the probe and the sample while measuring the topography or some other surface property of the sample as described, e.g., in Hansma et al. U.S. Pat. No. RE 34,489; Elings et al. U.S. Pat. No. 5,266,801; and Elings et al. U.S. Pat. No. 5,412,980.

In a common configuration, the probe is often coupled to an oscillating actuator or drive that is used to drive the probe at or near a resonant frequency of cantilever. Alternative arrangements may measure the deflection, torsion, or other motion of cantilever. The probe is often a microfabricated cantilever with an integrated tip.

Commonly, an electronic signal is applied from an AC signal source under control of an SPM controller to cause the actuator or scanner to drive the probe to oscillate. The probe-sample interaction is typically controlled via feedback by controller. Notably, the actuator may be coupled to the scanner and the probe but may be formed integrally with the cantilever of the probe as part of a self-actuated cantilever/probe.

AFMs may be designed to operate in a variety of modes, including contact mode and oscillating mode. Operation is accomplished by moving either the sample or the probe assembly up and down relatively perpendicular to the surface of the sample in response to a deflection of the cantilever of the probe assembly as it is scanned across the surface. Scanning typically occurs in an “x-y” plane that is at least generally parallel to the surface of the sample, and the vertical movement occurs in the “z” direction that is perpendicular to the x-y plane. Note that many samples have roughness, curvature and tilt that deviate from a flat plane, hence the use of the term “generally parallel.” In this way, the data associated with this vertical motion can be stored and then used to construct an image of the sample surface corresponding to the sample characteristic being measured, e.g., surface topography. In one mode of AFM operation, known as TappingMode™ AFM (TappingMode™ is a trademark of the present assignee), the tip is oscillated at or near a resonant frequency of the associated cantilever of the probe. A feedback loop attempts to keep the amplitude of this oscillation constant to minimize the “tracking force,” i.e. the force resulting from tip/sample interaction. Alternative feedback arrangements keep the phase or oscillation frequency constant. As in contact mode, these feedback signals are then collected, stored, and used as data to characterize the sample. Note that “SPM” and the acronyms for the specific types of SPMs, may be used herein to refer to either the microscope apparatus or the associated technique, e.g., “atomic force microscopy.” In a recent improvement on the ubiquitous TappingMode™ AFM, called Peak Force Tapping® (PFT) Mode, discussed in U.S. Pat. Nos. 8,739,309, 9,322,842 and 9,588,136, which are expressly incorporated by reference herein, feedback is based on force (also known as a transient probe-sample interaction force) as measured in each oscillation cycle.

Regardless of their mode of operation, AFMs can obtain resolution down to the atomic level on a wide variety of insulating or conductive surfaces in air, liquid, or vacuum by using piezoelectric scanners, optical lever deflection detectors, and very small cantilevers fabricated using photolithographic techniques. Because of their resolution and versatility, AFMs are important measurement devices in many diverse fields ranging from semiconductor manufacturing to biological research.

In this regard, AFMs may be employed in automated applications, including in high-precision manufacturing processes such as in semiconductor fabrication. Because AFMs can provide high resolution measurement of nanoscale surface features (e.g., topography), AFM has proven to be useful in the semiconductor space.

There are various analyses that can be performed on the acquired AFM data to ascertain different characteristics about a particular sample. Depending on the sample being studied and its intended use, the characteristics of interest and analyses used may vary. For example, in semiconductor fabrication and wafer bonding processes, there may be copper pads surrounded by a dielectric. In such a scenario, planarity between the copper pads and the surrounding dielectric is sought. There is a threshold on how much recess or protrusion between the boundary of the copper pads and the dielectric can be tolerated. Furthermore, with regard to the dielectric itself, planarity across the entire sample is desired. Additionally, planarity is desired across the copper pads themselves.

Planarity across the whole of the sample is the goal of the planarization process. However, determining whether the resulting sample falls within the particular thresholds to perform its semiconductor functions has proven to be a time intensive, and thus costly, process. Existing AFM analyses such as Depth, CFA & FinFET, are too application specific to be useful in this space. With known techniques, user would need to manually identify the areas where features are expected to be present, and then each of those areas would require individual analysis to discern its topographical and spatial characteristics. Such a time intensive process is not practical for a high-volume-manufacturing environment.

Considering depth analysis as an example, this is a histogram-based analysis that returns Z information in an AFM image. CFA is an analysis that analyzes square features in a square lattice and compares their sub-features. FinFet analysis is designed to measure the fin height, gate height and gate to fin height for each fin in an image by comparing the image to a CAD clip of the same region. Useful data can be acquired using these existing analyses, but due to the unique nature of the problem, a user would have to spend significant time and effort setting up the calculations, to the point that they are not practical as a high-volume-manufacturing solutions. These analyses become even more intensive when the number of pads or the absolute position of those pads is unknown.

What is needed is a means for a user to acquire meaningful data about spatial positioning and topographical comparison for features of a particular sample quickly and with minimal user intervention.

### SUMMARY OF THE INVENTION

The preferred embodiments overcome the drawbacks of current AFM data analysis techniques by enabling autonomous measurement of multiple key metrics on multiple regions of interest within a single AFM image without any user intervention to position those regions-of-interest (ROI). Previously, if a customer wanted to acquire similar data, they would have to manually process the data, which would require many dedicated man-hours. With this invention, a user can obtain meaningful data about the quality of the sample in a couple minutes or less. Since photolithography is an ever-evolving discipline, the data needed for quality assurance is also evolving. This invention helps to satisfy the need for users to check the quality of their samples quickly and with minimal human intervention.

The present invention is particularly useful for analysis for novel bonding pads in a hybrid bonding process employed in semiconductor fabrication. Auto pad detection creates an ease-of-use environment that does not require a priori knowledge of the number of pads or the absolute positions of those pads in the AFM image. The AFM images in most cases have greater than twenty pads. To accurately place measurement regions-of-interest (“ROI”) over all pads in an image over many images is now practical for a high-volume-manufacturing environment.

Auto pad detection ensures that the subsequent measurement ROIs are well placed on each pad for accurate, repeatable and reproducible metrology. The metrology at this process step requires sub-nm precision and this is only possible if the measurement ROIs are placed precisely on every measurement run. Shifts of the measurement ROI with respect to the pad will measure slightly different regions on the pad. Due to the inherent pad topography, this shift will thus generate a data set with poor repeatability.

The present invention overcomes this and the aforementioned drawbacks of current AFM analyses by using several algorithms to analyze AFM acquired data and return information about the quality of the sample. The invention combines a lattice detection algorithm with a novel lattice alignment technique. After applying both detection and alignment steps, the found lattice is used to analyze each feature's localized depth, variance, slope and more. The returned data can then be used to determine the quality of the sample. The present metrology method can be used to analyze any feature in a periodic lattice as well as contact folds and other topographical and spatial features of samples.

According to a preferred embodiment, a metrology method for analyzing an AFM image includes calculating the periodicity of the AFM image using Fast Fourier Transform Autocorrelation. Next, the method includes searching radially outwards from the center of the image to find peaks in periodicity. Then, the method includes quantifying circular shells of peaks in periodicity to obtain possible lattice period and angle. Further, the image may be downsampled for faster cost calculation. Next, a lattice mask is constructed using the previously acquired lattice period and angle. Then, the lattice mask is overlaid on the image, allowing the algorithm to distinguish feature pixels from background pixels. Further, the user input parameters are applied to the alignment calculation. From here, the method may vary depending on the data desired by the user.

In one aspect, the standard deviation of the background pixels is calculated and that value is set as the cost. Then, an offset of the lattice mask overlay is applied and the cost is recalculated. The cost is calculated at each offset in a 1.2 period range to cover all alignment options. Finally, the offset that gives the minimum cost is found and set as the final lattice alignment. This embodiment using standard deviation is likely to be used when the background is rough.

In a further aspect, the median between the background pixels and the features pixels is calculated and set as the cost. Then, an offset is applied to the lattice mask overlay and the cost is recalculated. The cost is calculated at each offset in a 1.2 period range to cover all alignment options. Finally, the offset that gives the maximum cost is found and set as the final lattice alignment. In this embodiment, the median is likely preferred when the background is smooth.

According to another aspect of the preferred embodiments, the method further comprises iterating over 2D model types including at least two of square, rectangular, hexagonal, and oblique, and then selecting the periodicity of the lattice type that produces the smallest deviation between the model lattice type and the acquired data.

In yet another aspect of the preferred embodiments, the method further includes applying an adaptive flattening algorithm to the sample image.

In another embodiment, a metrology method includes generating an image of a sample using atomic force microscopy (AFM) data, and calculating a periodicity of features of the image. Next, the method searches for at least one peak in the periodicity, and obtains a feature period and a lattice angle. The method then constructs a lattice mask template using the feature period and the lattice angle, and overlays the image with the lattice mask template. Then the method performs an alignment calculation to determine a cost, and applies an offset of the lattice mask template to the image and recalculates the cost. The applying and the recalculating steps are repeated to determine an alignment between the lattice mask template and the image.

In another embodiment, an AFM for collecting data of a sample AFM includes a probe that interacts with a surface of the sample, and a controller that controls the probe-sample interaction and collect atomic force microscopy (AFM) data of a sample having an array of periodic features. The controller uses the AFM data to generate a sample image having feature pixels and background pixels, and calculates a periodicity of the features. Further, the controller identifies peaks in the periodicity to determine a feature period and a lattice angle, and constructs a lattice mask template using the feature period and the lattice angle. Next, the image is overlayed with the lattice mask template, and the controller performs an alignment calculation to determine a cost. An offset of the lattice mask template is applied to the image and the cost is recalculated. The applying and the recalculating steps are repeated to determine an alignment between the lattice mask template and the image, particularly important in semiconductor fabrication.

According to another aspect of this embodiment, the controller performs the alignment step by at least one of a) calculating a standard deviation of the background pixels and setting the standard deviation as the cost value, and b) calculating a median of the background pixels and the feature pixels, and setting the median as a cost value. The controller may further determine an offset of the lattice that establishes a minimum cost value if the standard deviation is calculated, and determines the offset of the lattice that establishes a maximum cost value if the median is calculated.

These and other features and advantages of the invention will become apparent to those skilled in the art from the following detailed description and the accompanying drawings. It should be understood, however, that the detailed description and specific examples, while indicating preferred embodiments of the present invention, are given by way of illustration and not of limitation. Many changes and modifications may be made within the scope of the present invention without departing from the spirit thereof, and the invention includes all such modifications.

### BRIEF DESCRIPTION OF THE DRAWINGS

Preferred exemplary embodiments of the invention are illustrated in the accompanying drawings in which like reference numerals represent like parts throughout, and in which:

FIG. 1 is an image of the scanning probe microscope system;

FIG. 2A is an image of raw AFM data;

FIG. 2B is a schematic drawing showing the step of detecting periodicity in the raw AFM data;

FIG. 2C is a schematic drawing showing the step of analyzing rings of periodicity in the AFM data;

FIG. 2D is a schematic drawing showing the step of generating a lattice from the AFM data;

FIG. 3 is a flow diagram of the present metrology method of the preferred embodiments;

FIG. 4A is an image of raw AFM data;

FIG. 4B is an image of the raw AFM data of FIG. 4A, after the application of an adaptive flatten to remove image tilt;

FIG. 4C is an image of a periodicity map acquired with Fast Fourier Transform autocorrelation of the flattened AFM data of FIG. 4B;

FIG. 4D is an image illustrating the peaks in periodicity of FIG. 4C;

FIG. 4E is an image of a lattice mask template; and

FIG. 5 is sketch of a hexagonal lattice showing the features of interest and differences in height between them.

### DETAILED DESCRIPTION OF THE PREFERRED EMBODIMENT

The preferred embodiments are directed to a metrology method for analyzing spatial and topographical data of 2D elements/features in a lattice from raw atomic force microscopy (AFM) data. The methods described herein combine a lattice detection algorithm with a novel lattice alignment technique. After applying both detection and alignment steps, the found lattice is used to analyze each feature's localized depth, variance, slope and more. This invention helps to satisfy the need for users to check the quality of their samples quickly and with minimal user intervention.

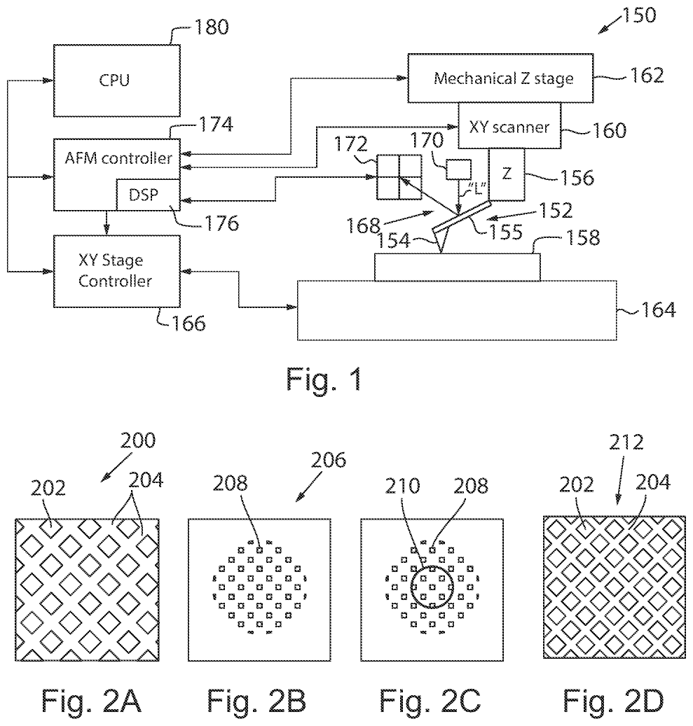

Turning first to FIG. 1, a scanning probe microscope instrument 150 (e.g., AFM) according to a preferred embodiment is shown. In this embodiment, a probe 152, having a tip 154 extending from a distal end of a cantilever 155 is held by a probe holder (not shown) supported by piezoelectric tube scanner 156. Scanner 156 may be a “Z” or vertical scanner responsive to sample properties in the closed loop control system to position the tip 154 relative to a sample 158 during AFM imaging. Tube scanner 156 is coupled to an XY scanner 160, preferably also a piezoelectric tube, that is used to raster the probe tip 154 relative to the sample 158 surface during AFM operation. Notably, a scanned sample may be employed as an alternative. A mechanical Z-stage 162 is included for providing large movement in Z between tip 154 and sample 158, for example, during AFM image acquisition start-up to engage tip 154 and sample 158.

Sample 158 is mounted on an XY stage 164 that primarily provides coarse XY motion to position probe 152 at a region of interest of sample 158. An XY stage controller 166 controls stage 164 to locate the probe/sample at that region of interest. Again, however, stage 164 may be configured to provide relative scanning motion (e.g., raster) between tip 154 and sample 158 at a selected scan speed. Controller 166 is also responsive to AFM controller 174 to position the image scan at a region of interest. Controllers 166, 174 are implemented by a computer 180.

In operation, after tip 154 is engaged with sample 158, a high speed scan of the sample is initiated with XY scanner 160 in an AFM mode of operation (e.g., PFT mode), as discussed previously. As tip 154 interacts with the surface of sample 158, the probe 152 deflects and this deflection is measured by an optical beam-bounce deflection detection apparatus 168. Apparatus 168 includes a laser 170 that directs a beam “L” off the backside of cantilever 155 and toward a photodetector 172 which transmits the deflection signal to, for example, a DSP 176 of AFM controller 174 for high speed processing of the deflection signal.

AFM controller 174 continuously determines a control signal according to the AFM

operating mode, and transmits that signal to the piezo tube scanner 156 to maintain the Z position of probe 152 relative to sample 158, and more specifically, to maintain deflection of the probe at the feedback set point.

Turning to FIGS. 2A-2D, a series of schematic drawings depicting the progression

of analysis of the AFM data according to the present metrology method are shown. In FIG. 2A the raw AFM data is shown with image 200. This raw AFM data is generated by the above described scanning probe microscope instrument and methodology. The data consists of features 202 and background 204. Next, FIG. 2B is a schematic representation 206 of detecting the periodicity in the raw AFM data. This preferably is achieved by Fast Fourier Transform (FFT) autocorrelation to find the peaks and periodicity in the raw AFM data. The image is correlated with itself, and the peaks represent points 208 where the image is symmetrical with itself. Further, in FIG. 2C, a schematic drawing of a ring of periodicity 210 found in the data is shown. Each point 208 in FIG. 2C represents a peak in periodicity. The locations of these peaks relative to the center and relative to each other in terms of distance and 2D-angle is quantified and used to construct different lattices (described in more detail below). FIG. 2D is a schematic 212 representation of a lattice that may be generated for use as a mask in extracting sample information, in regions of features 202 adjacent regions of background 204.

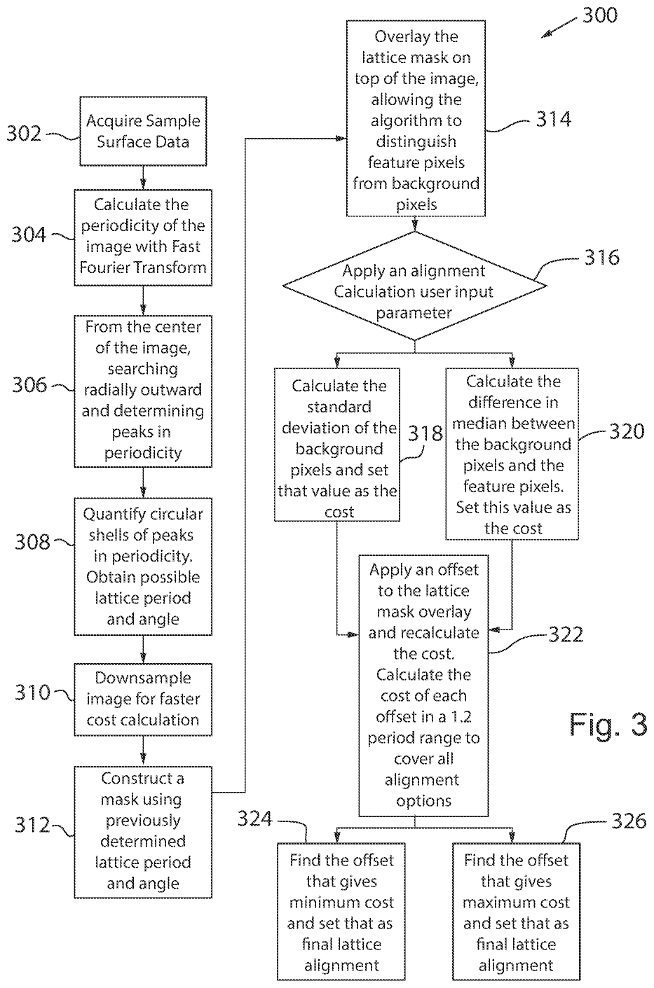

Now turning to FIG. 3, a simplified diagram of the present metrology method 300 is shown. At Step 302, the raw AFM surface data is collected from the sample. Next, at Step 304, the periodicity of the image is calculated using Fast Fourier Transform (FFT). At Step 306, rings in periodicity (see FIG. 2C) are found by searching radially outward from the center of the image. In the case of a hexagonal lattice, collections of four may be used in finding the rings. When using different lattices (rectangular, triangular, octagonal, etc.), other collections may be sought. These rings in periodicity provide information about the location of the peaks relative to the center in terms of distance and also provide information about the distance and angle of the peaks relative to each other. Again, multiple rings in periodicity are found moving radially outward from the center. Then, at Step 308 the circular shells of peaks in periodicity are quantified and possible lattice periods and angles are obtained. At Step 310, the image may be down sampled for faster cost calculation. Then, at Step 312, a lattice mask is constructed using the previously acquired lattice periods and angles. Several of these lattices, like that shown in FIG. 2D, are generated.

At Step 314, the lattice mask is overlaid on top of the image, allowing the algorithm to distinguish feature pixels from background pixels. Here the mask matrix is added/multiplied with the image matrix to extract feature pixels. The mask 212 (FIG. 2D) breaks up the image into black area and white area pixels. The white area pixels represent the sample features, while the black area pixels represent the background. Then, at Step 316, an alignment calculation user input parameter is applied. The user may choose between using a standard deviation calculation or a median calculation. Standard deviation is likely to be applied when the background is rough, while median is likely to be applied when the background is smooth.

Depending on which parameter the user chooses, the next step may differ. If the user chooses standard deviation, the standard deviation of the background pixels (black region) is calculated and that standard deviation value is set as the cost at Step 318. Then, at step 322, an offset of the lattice mask overlay is applied, and the cost is recalculated. The cost is calculated at each offset in preferably, a 1.2 period range to cover all alignment options. This is an exhaustive search over the area of one unit cell so that all possible offsets are tested. Finally, at step 324, the offset that gives minimum cost is found and set as the final lattice alignment.

The method varies if the user chooses the median as the input parameter. In this case, the next step following step 316 is step 320, in which the difference in median between the background pixels (black region) and the feature pixels (white region) in FIG. 2D is calculated. The difference between the median of the background pixels 204 and the feature pixels 202 is calculated and set as the cost. Next, at Step 322, an offset of the lattice mask overlay is applied, and the cost is recalculated, as in the standard deviation case. The cost is calculated at each offset in a 1.2 period range to cover all alignment options. This is an exhaustive search over the area of one unit cell so that all possible offsets are tested. Finally, at Step 326, the offset that gives the maximum cost value is found and set as the final lattice alignment.

Once the cost is properly calculated, the final lattice alignment is determined, and the design of features is established. For example, if it is established that the features are a series of concentric rectangles, pixels can be extracted from the AFM image corresponding to every area of the rectangle and specific pixels can be analyzed corresponding to specific parts of the features.

Note that when the 2D lattice type is unknown, one can iterate over all possible lattice types in 2D: square, rectangular, hexagonal, or oblique (see https://mwikipediamrglwikilBravais lattice), and select periodicity of the lattice type which results in the smallest deviation between the model lattice and the acquired data. Here, the smallest deviation corresponds to the best cost of alignment.

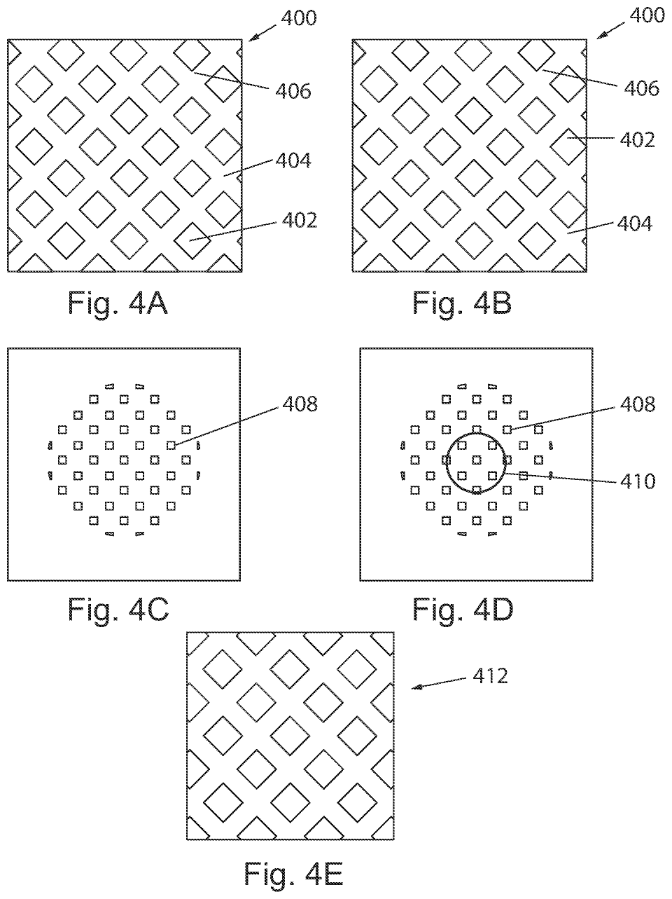

Turning now to FIGS. 4A-4E, a series of images showing the progression of

analysis of the AFM data according to the present metrology method is shown. In FIG. 4A the raw AFM data is shown. The image 400 shown in FIG. 4A would be generated at step 302 of the above described metrology method. The data consists of features 402 and background 404. Defects 406 may also be present in the sample and resulting data. Next, FIG. 4B is an image of the AFM data after application of an “adaptive flatten” to remove image tilt. FIG. 4C is an image showing the periodicity map acquired with Fast Fourier Transform autocorrelation. The points 408 in the image represent the peaks in the periodicity.

FIG. 4C corresponds to step 304 of the above described metrology method. FIG. 4D is an image showing a ring of periodicity 410. FIG. 4D corresponds to Step 306 from the above described metrology method. Further yet, FIG. 4E is an image showing a lattice mask template 412 generated using the distribution of the peaks. This mask is generated at Step 312 above. This lattice mask template 412 is then overlaid on top of the AFM image. In doing so, the mask matrix is multiplied with the image matrix so only certain pixels are analyzed. This corresponds to Step 314 described above.

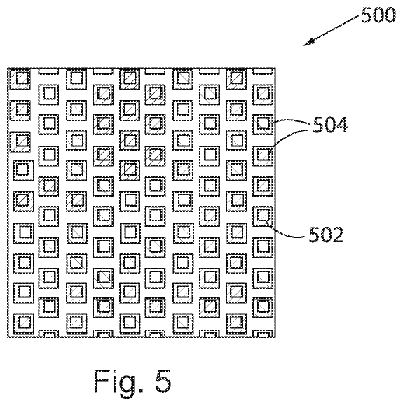

Turning to FIG. 5, a sketch of a hexagonal lattice 500 showing the features of

interest and differences in height between them is shown. Rather than a square lattice, a hexagonal lattice is shown here. The dark squares 502 represent the location of design features of interest 502 (e.g., 402 of FIG. 4A) as found by the present method. Once the features of interest 502 are identified, they can be analyzed to quantify the distribution of height between the features 502. The shading 504 over the features 502 represents differences in height between the features 502. FIG. 5 is a sketch of the results that would be acquired at step 324 or 326 above. The center of FIG. 5, where the squares have no shading, indicates that the features in this portion of the sample may be missing or are barely printed on the wafer. When the wafer is printed, it is always periodic, so the features 502 in theory should exist at every square in the image. This information regarding each feature's 502 localized depth, variance, slope height and more is of great importance to the quality of the sample and its functionality.

The preferred embodiments are particularly useful in semiconductor manufacturing.

Recess analysis, for example, enables critical metrology for IC manufacturing processes in which two semiconductor wafers with patterned surfaces are bonded together. This wafer-to-wafer bonding requires highly accurate topographical knowledge of the post polished (CMP) wafer surfaces that consist of metal pads surrounded by dielectric material. The effectiveness of the bonding requires a very flat surface. Recess analysis calculates the height difference, known as dishing, of the metal pads with respect to the surrounding dielectric, the local slopes of the dielectric material in proximity of the metal pads, as well as global planarity over the entire field of view.

The output of the recess analysis permits the IC manufacturer to make critical process decisions based on the percent of out of specification roughness and slope regions.

Although the best mode contemplated by the inventors of carrying out the present invention is disclosed above, practice of the above invention is not limited thereto. It will be manifest that various additions, modifications and rearrangements of the features of the present invention may be made without deviating from the spirit and the scope of the underlying inventive concept.

We claim:

1. A metrology method comprising the steps of:
using atomic force microscopy (AFM) data of a sample having an array of periodic features to generate a sample image having feature pixels and background pixels;
calculating a periodicity of the features;
identifying peaks in the periodicity to determine a feature period and a lattice angle;
constructing a lattice mask template using the feature period and the lattice angle;
overlaying the image with the lattice mask template;
performing an alignment calculation to determine a cost;
applying an offset of the lattice mask template to the image and recalculating the cost; and
repeating the applying and the recalculating steps to determine an alignment between the lattice mask template and the image.

2. The method of claim 1, wherein the performing step includes at least one of a) calculating a standard deviation of the background pixels and setting the standard deviation as the cost value, and b) calculating a median of the background pixels and the feature pixels, and setting the median as a cost value.

3. The method of claim 2, further comprising determining the offset of the lattice that establishes a minimum cost value if the standard deviation is calculated, and the offset of the lattice that establishes a maximum cost value if the median is calculated.

4. The method of claim 1, further comprising extracting data with respect to the features after applying the alignment.

5. The method of claim 4, wherein the data corresponds to at least one of feature characteristic including height, depth, shape, uniformity, variance and slope.

6. The method of claim 5, further comprising comparing the at least one feature characteristic to a known model to determine feature quality.

7. The method of claim 6, wherein the comparing step is used in semi conducting fabrication recess analysis.

8. The method of claim 1, wherein the features are 2D-periodic features and identifying peaks in the periodicity step begins at a center of the sample image and continues radially outwardly.

9. The method of claim 8, further comprising:
iterating over 2D model types including at least two of square, rectangular, hexagonal, and oblique; and
selecting the periodicity of the lattice type that produces the smallest deviation between the model lattice type and the acquired data.

10. The method of claim 1, wherein the calculating the periodicity step is performed using a Fast Fourier Transform (FFT) algorithm.

11. The method of claim 1, wherein the lattice mask template is hexagonal.

12. The method of claim 1, further comprising applying an adaptive flattening algorithm to the sample image.

13. A metrology method comprising the steps of:
generating an image of a sample using atomic force microscopy (AFM) data;
calculating a periodicity of features of the image;
searching for at least one peak in the periodicity;
obtaining a feature period and a lattice angle;
constructing a lattice mask template using the feature period and the lattice angle;
overlaying the image with the lattice mask template;
performing an alignment calculation to determine a cost;
applying an offset of the lattice mask template to the image and recalculating the cost; and
repeating the applying and the recalculating steps to determine an alignment between the lattice mask template and the image.

14. The metrology method of claim 13, wherein the cost is calculated over an entire area of one unit cell.

15. The metrology method of claim 13, further comprising a step of downsampling the image for faster calculation of the cost.

16. The metrology method of claim 13, wherein the searching for at least one peak in periodicity step begins from a center of the image and continues radially outwardly.

17. The metrology method of claim 13, wherein the calculating periodicity step is accomplished by using Fast Fourier Transform (FFT) algorithm.

18. An AFM for collecting data of a sample AFM comprising:
a probe that interacts with a surface of the sample;
a controller that controls the probe-sample interaction and collect atomic force microscopy (AFM) data of a sample having an array of periodic features; and
wherein the controller:
uses the AFM data to generate a sample image having feature pixels and background pixels;
calculates a periodicity of the features;
identifies peaks in the periodicity to determine a feature period and a lattice angle;
constructs a lattice mask template using the feature period and the lattice angle;
overlays the image with the lattice mask template;
performs an alignment calculation to determine a cost;
applying an offset of the lattice mask template to the image and recalculating the cost; and
repeats the applying and the recalculating steps to determine an alignment between the lattice mask template and the image.

19. The AFM of claim 18, wherein the controller performs the alignment step by at least one of a) calculating a standard deviation of the background pixels and setting the standard deviation as the cost value, and b) calculating a median of the background pixels and the feature pixels, and setting the median as a cost value.

20. The AFM of claim 19, wherein the controller further determines the offset of the lattice that establishes a minimum cost value if the standard deviation is calculated, and determines the offset of the lattice that establishes a maximum cost value if the median is calculated.
